(19) United States
(12) Patent Application Publication
(10) Pub. No.: US 2002/0158267 A1
(43) Pub. Date: Oct. 31, 2002

(54) Gallium containing luminescent powders and method of manufacturing same

(76) Inventor: P. Victor Kelsey JR., Wilmington, DE (US)

Correspondence Address: Robert D. Traver, SHERIDAN ROSS P.C., Suite 1200, 1560 Broadway, Denver, CO, 80202-5141, US

(21) Appl. No.: 10/081,288

(22) Filed: Feb. 21, 2002

Related U.S. Application Data
(60) Provisional application No. 60/270,501, filed on Feb. 21, 2001.

(51) Int. Cl. H01L 33/00

(52) U.S. Cl. 257/103

(57) ABSTRACT

The invention provides gallium nitride phosphor materials and methods of manufacturing the gallium nitride phosphor materials. By making use of these methods, it is possible to produce members of the family of gallium nitride materials, with or without alloying elements or fluxing compounds, in powdered form having the required purity and particle size to perform as highly efficient electroluminescent emitters in many display applications.

This application claims the benefit of Provisional Patent Application Serial No. 60/270,501 filed in the U.S. Patent and Trademark Office on Feb. 21, 2001.

### FIELD OF THE INVENTION

This invention is directed to methods of producing gallium nitride compositions in powdered form. These powders can be produced with a specified purity and particle size having applications as phosphors in many types of display devices.

### BACKGROUND OF THE INVENTION

Luminescent materials or phosphors containing gallium have been investigated and used commercially for many years. These gallium containing semiconducting materials, by virtue of their unique band gap structures, emit photons when electrons previously excited from the valence band into the conduction band re-combine with holes in the valence band, giving off energy in the form of photons. While the wavelength of these photons is partially dependent upon the distance of the band gap, which is a function of the chemical composition of the host material (gallium arsenide for example), it can also be a function of intentionally added dopants or alloys that introduce energy levels within the bandgap, thereby altering the emission wavelength. For instance, cadmium sulfide is often added to zinc sulfide to shrink the bandgap, thereby shifting the emission wavelength to lower energies or higher wavelengths. Other additions to the host material, called activators, are generally dopants at much lower concentrations ranging from approximately 2 atomic percent down to the 100 ppm range. These activators form donor and/or acceptor levels within the bandgap thereby altering the emission wavelength. In other instances the activator ions such as europium, terbium or thulium are added to hosts such as yttrium oxide and gallium nitride to emit photons of a wavelength associated with that activator via a charge transfer from the host to the emitting ion.

In recent years there has been a tremendous growth in the development of gallium containing thin film devices for use in Light Emitting Diodes (LED) and Laser Diodes (LD). Compounds such as GaP, GaₓAl₁₋ₓP, GaₓIn₁₋ₓN, GaAs, GaAlAs, GaN, GaAl₁₋ₓN, GₓIn₁₋ₓN and alloys of these materials are currently being manufactured via various thin film techniques. Gallium oxide based materials are also known to be efficient luminescent hosts under different excitation modes including CRT and typical fluorescent excitation. While the oxide materials are fabricated in the standard powdered form (1 to 20 microns), the nitride, phosphide, and arsenide compounds are not available in a powdered form useful in most commercial displays.

Gallium nitride and zinc sulfide have similar crystal structures including wurtzite (hexagonal) and zincblende (cubic) structures with comparable lattice parameters. Additionally, both gallium nitride and zinc sulfide are direct bandgap semiconductors with bandgaps of approximately 3.3 eV and 3.7 eV respectively. Zinc sulfide however, has been used extensively in powdered form as a phosphor in display systems for more than sixty years. Indeed, zinc sulfide has been the most widely used television phosphor in both black and white and color displays. It has also been investigated for use in Field Emission Displays (FED)s and Vacuum Fluorescent Displays (VFD)s. Unfortunately, in these displays sulfur migration and poisoning of cathodes resulting from a breakdown of zinc sulfide under the electric fields present in these devices remains a serious problem. Gallium nitride has not been used in such applications because it is very difficult to synthesize in powdered form. Until recently, the best method cited in the literature involves heating molten gallium metal in a crucible under an atmosphere of ammonia at a temperature of 1273K. This process is described by Blakas, C. M., and Davis, R. F. Synthesis Routes and Characterization of High-Purity, Single-Phase Gallilum Nitride Powders, J. Am. Ceram. Soc., 79(9) 2309-12 (1996). The product is almost brown in appearance, and therefore, unsuitable as a phosphor. Two newer methods of synthesizing GaN phosphors have recently been cited. In the first, ZnO particulate is used as a nucleating surface as trimethylgallium (TMG), ammonia, dimethylzinc (DEZ) and silane (SiH₄) are fed into a tube furnace at about 950° C. containing the ZnO. GaN:Si and GaN:Zn films form on the surface of the ZnO. Upon annealing the resulting powder at 700° C., a phosphor with high luminance is formed (Japanese Abstract JP008035A2; Phosphor and Production Thereof, Hitoshi and Shigeo, Jan. 11, 2000). In the other citation, powdered GaN with a dopant (assumed to be either Zn or Si) is formed in a tube furnace by passing ammonia over a boat containing a sulfur and oxygen-bearing compound placed upstream of a gallium-containing compound (gallium oxide, for instance). Sulfur and oxygen are released via thermal decomposition and fed downstream with the ammonia to react with the gallium compound to form gallium nitride. The sulfur and oxygen create a buffer to prevent further reduction of the gallium nitride to gallium metal (Japanese Abstract JP 192035A2; Production of Gallium Nitride Phosphor, Yoshitaka, Junko, Fumiaki, Hitoshi, and Yuji).

Recently, considerable improvement has been made in the development of the family of gallium nitride materials with alloying elements of In, Al, Mg and others. These materials are highly efficient electroluminescent emitters, but can only be fabricated in thin film form. Thus there still exists a need for gallium-containing luminescent materials in powdered form with the required purity and particle size necessary for use in many types of display devices.

### SUMMARY OF THE INVENTION

One aspect of the present invention is a powdered gallium phosphor material. The powdered gallium phosphor may contain activators and/or fluxes. The powder comprises a particle size range useful in most display applications preferably in the range of 2-10 microns.

Another aspect of the present invention provides a method of producing a powdered gallium phosphor material. The method is directed to gas atomization of a molten gallium metal under nitrogen-bearing gas to produce a powdered gallium phosphor. The resulting powder may then be ground to a desired particle size. The phosphor material may then be fired in the presence of a nitrogen-bearing gas to further the reaction or to incorporate activators or fluxing compounds.

Another aspect of the present invention is a method of producing a powdered gallium phosphor material in which gallium metal is melted in the presence of a nitrogen-bearing gas before being cooled and exposed to air to create a powdered gallium phosphor. The resulting powder may then be ground to a desired particle size. The phosphor material may also be refired in the presence of a nitrogen-bearing gas to further the reaction or to incorporate activators or fluxing compounds.

### BRIEF DESCRIPTION OF THE DRAWINGS

FIG. 1. Schematic of the INEL inert gas atomization system.

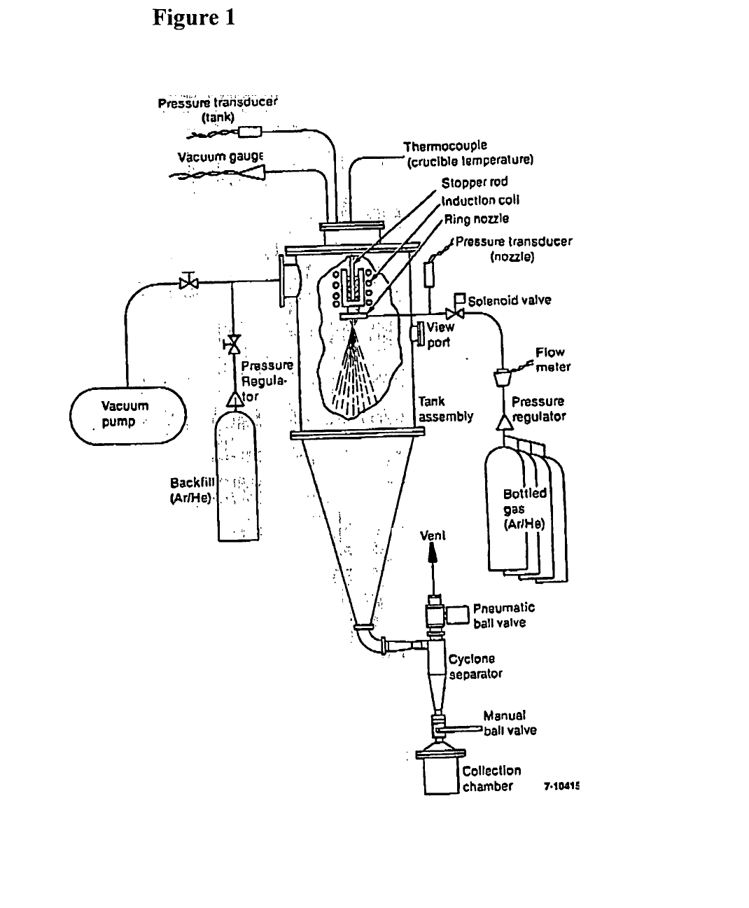

FIG. 2. Two of the most successful nozzle/crucible designs evaluated for gas atomization.

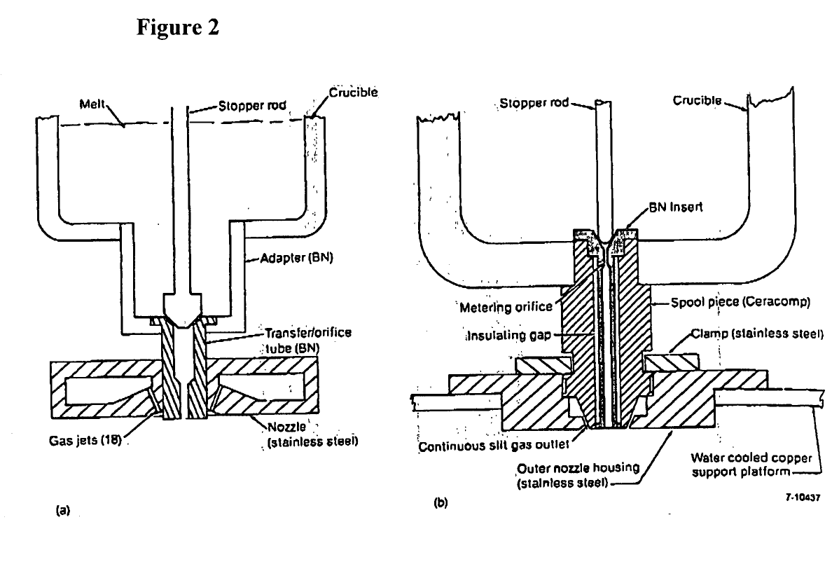

### DETAILED DESCRIPTION OF THE INVENTION

Gas atomization of a molten metal is one method of producing fine (1 to 100 micron) metal powders with compositions ranging from copper to steel. The process impinges a stream of molten metal inside a tank with a stream of high velocity inert gas (for example nitrogen or argon) causing a rapid particulation or atomization of the metal into fine droplets which are quickly cooled by an inert gas. Breakup of the molten metal results primarily from instabilities caused by a light fluid pushing against a heavier fluid, and partly by viscous forces which tend to distort the outer periphery of the molten droplet. In this way, the stabilizing influence of surface tension is disrupted by an external force, namely high velocity gas flow causing breakup of the metal. The kinetics of all atomization processes typically involves several steps. The extension of the bulk liquid (e.g. molten metal) into sheets, jets, films, or streams is caused by accelerating the liquid in some prescribed manner. This includes the use of pressurized nozzles, simple gravity feed through an orifice, or off a rotating disk. Initiation of small disturbances at the liquid surface forms localized ripples, protuberances, or waves. Formation of short ligaments on the liquid surface results from fluid pressure or shear forces. Collapse of the ligaments into drops results from surface tension in the liquid. Further breakup of the liquid drops as they move through the ambient gaseous medium occurs by the action of fluid pressure or shear forces. Droplet breakup and atomization is essentially a competition between external dynamic pressure and viscous shear forces which tend to tear the drop apart, and the surface tension and internal viscous forces which tend to resist deformation and breakup. The total amount of energy required increases rapidly as the mean particle size decreases (i.e. as the total surface area increases). Breakup and atomization of liquid droplets is ultimately governed by how efficiently energy from the atomizing fluid can be coupled into the molten metal generating fine isolated particles. A widely used model for the breakup process pictures a drop of liquid moving in a gaseous medium which experiences secondary disintegration when the dynamic pressure due to gas stream velocity exceeds the restoring force due to surface tension.

One embodiment of the present invention provides a method for fabricating gallium-containing phosphors utilizing gas atomization of melts of gallium metal or gallium alloys or compounds. Semiconductor grade gallium or a gallium alloy is heated in an appropriate crucible in either a resistance heated furnace or an induction furnace to a temperature above the melting point of the alloy. The bottom of the crucible is opened to allow a stream of molten metal to flow into either an evacuated chamber or a chamber that has been evacuated and backfilled with nitrogen, ammonia, or another nitrogen-containing gas buffered with a sulfur-bearing gas including, but not limited to SO₂, SO₃, or H₂S. The stream is impinged by a jet of nitrogen-containing gas, which not only quickly cools the metal, but also breaks up the metal into small particles. The particles range in size from 1 to 500 microns, and are preferably between 1 and 20 microns. While the gas in standard atomization processes is often inert to the metal and is used only as a medium of atomization, the present invention employs the novel use of a nitrogen-containing gas that reacts with the atomized droplets to form a gallium nitride of the formula GaN₁₋ₓ wherein X ranges from 0 to 0.5 depending upon the process variables and the size of the atomized particle. The resultant powder can be further processed by standard phosphor synthesis methods by which the powder is fired in a controlled atmosphere furnace with a nitrogen/oxygen/hydrogen/sulfur ratio sufficient to form the nitride rather than the oxide or the metal. Ratios sufficient for the purpose of forming the nitride include nitrogen:oxygen greater than 10:1; sulfur:hydrogen greater than 1:1; and hydrogen:oxygen greater than 1:1.

In one embodiment of the present invention, the atmosphere is substantially oxygen free and the powder is fired in a controlled atmosphere of nitrogen and hydrogen in which the nitrogen:hydrogen ratio ranges from about 200:1 to about 1:100 and is preferably 1:3. In gases having nitrogen:hydrogen ratios less than 1:1, a second firing of the material in a nitrogen:hydrogen gas having a nitrogen:hydrogen ratio greater than 1 :1 may be necessary to obtain the maximum luminescence from the final product. In each firing, the addition of some sulfur to the nitrogen/hydrogen gas may be required to inhibit the formation of gallium metal. The additional sulfur is preferably present at a level of less than 10% of the final gas mixture.

Activator elements and fluxing compounds can be added in the firing step. Activator elements can also be added in the melt stage as long as the melt characteristics (i.e. viscosity and melting points) are not drastically altered. Suitable activator elements include europium, terbium, thulium, manganese, copper, silver, praseodymium, cerium, dysprosium, holmium, ytterbium, samarium, gadolinium, chlorine, bismuth, titanium, aluminum, sodium, lithium, potassium, indium, zinc, magnesium, silicon, germanium and combinations of these elements. Fluxes are generally salts that are added in the range of 1-25% by weight to the phosphor powder mix prior to the firing step and are preferably present in the range of 1-2%. They enhance diffusion of ions/atoms and promote better particle crystallinity. The resulting powders will exhibit highly efficient luminescence under the excitation of a cathode ray tube, vacuum fluorescence, or electroluminescence with the emitting wavelengths being a function of the specific gallium alloy fabricated (i.e. GaN or GaAlN), and the addition of any activators. Suitable fluxes include sodium chloride, lithium chloride, potassium chloride, lithium fluoride, lithium silicate, chlorides of magnesium, strontium, and barium, magnesium fluoride, barium fluoride and combinations of these fluxes.

Another embodiment of the present invention uses the direct nitridization of gallium metal or gallium oxide in a nitrogen/hydrogen atmosphere at temperatures ranging from about 1000K to about 2000K, with the best results obtained using temperatures from about 1200K to about 1400K. The gallium metal or oxide to be converted into nitride is placed in a fused silica or quartz boat or crucible, which in turn is put into a fused silica retort. The retort is flushed with a nitrogen, hydrogen, sulfur and oxygen-bearing gas for 30 minutes. The nitrogen and hydrogen component of the gas preferably includes such as ammonia or forming gas. The nitrogen and hydrogen component of the gas used to flush the retort can have a nitrogen and hydrogen composition of between 99% nitrogen/1% hydrogen and 5% nitrogen/95% hydrogen. Preferably, the nitrogen and hydrogen bearing gas used to flush the retort has a nitrogen and hydrogen composition of between 90% nitrogen/10% hydrogen and 25% nitrogen/75% hydrogen gas.

The sealed retort with a gas flow of one or more of the gases cited above is placed in a furnace at the desired temperature for a period ranging form 2 to 50 hours. After completing this reaction, the retort is removed from the furnace and allowed to cool to less than about 400K. Alternatively, the furnace is turned off and cooled to less than about 400K with the retort remaining in the furnace. The reacted powder is exposed to air only after cooling to less than about 400K. This method yields a gallium nitride powder of suitable purity for use in many types of display devices although the powder is often too coarse for some display applications. In order to meet certain particle size requirements, or to further react the powder, the powder may be ground by any method known in the art to the required size for immediate use, or refired in the gas atmosphere to complete the reaction or incorporate activators.

Compounds in the gallium nitride family of alloys include GaP, GaₓAl₁₋ₓP, GaₓIn₁₋ₓN, GaAs, GaAlAs, GaN, GaₓAl₁ₓN, GaₓIn₁₋ₓN wherein X ranges from 0.25 to 1. These compounds may also include activators such as rare earth ions (for example Eu, Tm, Tb, Er) as well as other ions or metals. Phosphors in this family of materials can be produced in powdered form using the methodology of the present invention. These powdered phosphors have utility in many types of emissive displays by virtue of their enhanced brightness and chemical stability. This family of phosphors emits efficiently under a variety of electronic excitation voltages ranging from very low voltages (15 to 100 volts) as in Vacuum Fluorescent Displays, to medium voltages (2 to 10 kilovolts) as in Field Emission Displays to high voltages (20 to 30 kilovolts) as in standard cathode ray tubes.

What is claimed is:

1. A powdered phosphor material comprising a member of the group consisting of GaP, GaₓAl₁₋ₓP, GaₓIn₁₋ₓN, GaAs, GaAlAs, GaN, GaₓAl₁₋ₓN, and GaₓIn₁₋ₓN wherein X is in the range of about 0.25 to about 1.

2. The phosphor material according to claim 1, wherein said powdered phosphor material additionally comprises an activator.

3. The powdered phosphor material according to claim 2, wherein said activator is selected from the group consisting of europium, terbium, thulium, manganese, copper, silver, praseodymium, cerium, dysprosium, holmium, ytterbium, samarium, gadolinium, chlorine, bismuth, titanium, aluminum, sodium, lithium, potassium, indium, zinc, magnesium, silicon, germanium and combinations thereof.

4. The phosphor material according to claim 1, wherein said powdered phosphor material additionally comprises a fluxing compound.

5. The phosphor material according to claim 4, wherein said fluxing compound is selected from the group consisting of sodium chloride, lithium chloride, potassium chloride, lithium fluoride, lithium silicate, chlorides of magnesium, strontium, and barium, magnesium fluoride, barium fluoride and combinations thereof.

6. The phosphor material according to claim 1, wherein the average particle size of said powder is in the range of about 1 micron to about 500 microns.

7. The phosphor material according to claim 1, wherein the average particle size of said powder is in the range of about 2 microns to about 10 microns.

8. A method of producing a powdered gallium phosphor material comprising:
i) heating a gallium metal to a temperature above the melting point of the metal to produce a molten gallium metal;
ii) directing said molten gallium metal into an evacuated chamber; and,
iii) impinging said molten gallium metal in said evacuated chamber with a nitrogen bearing gas to form a powdered gallium phosphor material.

9. The method of claim 8, wherein said gallium metal is semiconductor grade gallium.

10. The method of claim 8, wherein said gallium metal is a gallium alloy.

11. The method of claim 8, wherein said evacuated chamber is backfilled with a nitrogen-containing gas.

12. The method of claim 11, wherein said nitrogen-containing gas is selected from the group consisting of nitrogen, ammonia and mixtures thereof.

13. The method of claim 11, wherein said nitrogen-containing gas is buffered with a sulfur-bearing gas selected from the group consisting of SO₂, SO₃ and H₂S gas.

14. The method of claim 8, comprising the additional step of:
firing said powdered gallium phosphor material under a gas comprising nitrogen, hydrogen, oxygen and hydrogen.

15. The method of claim 14, wherein said firing step further comprises adding an activator element selected from the group consisting of europium, terbium, thulium, manganese, copper, silver, praseodymium, cerium, dysprosium, holmium, ytterbium, samarium, gadolinium, chlorine, bismuth, titanium, aluminum, sodium, lithium, potassium, indium, zinc, magnesium, silicon, germanium and combinations thereof.

16. The method of claim 14, wherein said firing step further comprises adding a fluxing compound selected from the group consisting of sodium chloride, lithium chloride, potassium chloride, lithium fluoride, lithium silicate, chlorides of magnesium, strontium, and barium, magnesium fluoride, barium fluoride and combinations thereof.

17. A method of producing a powdered gallium phosphor material comprising the steps of:
i) supplying a gallium material selected from the group consisting of gallium metal and gallium oxide;
ii) placing said gallium material into a fused silica retort;
iii) flushing said retort with a nitrogen, hydrogen, sulfur and oxygen bearing gas;
iv) heating said retort to a temperature between about 1000K and about 2000K for about 5 to about 50 hours;
v) cooling said retort to less than about 400K; and,
vi) exposing the gallium material within said retort to air to produce a powdered gallium phosphor material.

18. The method of claim 17, wherein the nitrogen, hydrogen, sulfur and oxygen bearing gas in said flushing step comprises ammonia.

19. The method of claim 17, wherein the nitrogen and hydrogen bearing gas comprises between about 99% nitrogen gas with about 1% hydrogen gas and about 5% nitrogen gas with about 95% hydrogen gas.

20. The method of claim 17, wherein the nitrogen and hydrogen bearing gas comprises between about 90% nitrogen gas with about 10% hydrogen gas and about 25% nitrogen gas with about 75% hydrogen gas.

21. The method of claim 17, comprising the additional step of:
grinding said powdered gallium phosphor material.

22. The method of claim 17, comprising the additional step of:
refiring said powdered gallium phosphor material under a gas comprising nitrogen, hydrogen, oxygen and hydrogen.

23. The method of claim 22, wherein said refiring step is conducted in the presence of an activator selected from the group consisting of europium, terbium, thulium, manganese, copper, silver, praseodymium, cerium, dysprosium, holmium, ytterbium, samarium, gadolinium, chlorine, bismuth, titanium, aluminum, sodium, lithium, potassium, indium, zinc, magnesium, silicon, germanium and combinations thereof.

24. The method of claim 22, wherein said refiring step is conducted in the presence of a fluxing compound selected from the group consisting of sodium chloride, lithium chloride, potassium chloride, lithium fluoride, lithium silicate, chlorides of magnesium, strontium, and barium, magnesium fluoride, barium fluoride and combinations thereof.

25. A method of producing a powdered gallium phosphor material comprising:
i) heating a gallium metal selected from the group consisting of semiconductor grade gallium and a gallium alloy to a temperature above the melting point of the metal to produce a molten gallium metal;
ii) directing a stream of said molten gallium metal into a chamber that has been evacuated and backfilled with a gas selected from the group consisting of nitrogen, ammonia, a sulfoxide-buffered nitrogen-containing gas and mixtures thereof;
iii) impinging said molten gallium metal in said evacuated chamber with a jet of nitrogen-bearing gas to form a powdered gallium phosphor material; and,
iv) firing said powdered gallium phosphor material under a gas comprising nitrogen, hydrogen, oxygen and hydrogen in the presence of an activator selected from the group consisting of europium, terbium, thulium, manganese, copper, silver, praseodymium, cerium, dysprosium, holmium, ytterbium, samarium, gadolinium, chlorine, bismuth, titanium, aluminum, sodium, lithium, potassium, indium, zinc, magnesium, silicon, germanium and combinations thereof and in the presence of a fluxing compound selected from the group consisting of sodium chloride, lithium chloride, potassium chloride, lithium fluoride, lithium silicate, chlorides of magnesium, strontium, and barium, magnesium fluoride, barium fluoride and combinations thereof.

26. A method of producing a powdered gallium phosphor material comprising the steps of:
i) supplying a gallium material selected from the group consisting of gallium metal and gallium oxide;
ii) placing said gallium material into a fused silica retort;
iii) flushing said retort with a nitrogen, hydrogen, sulfur and oxygen bearing gas comprising between about 90% nitrogen gas with about 10% hydrogen gas and about 25% nitrogen gas with about 75% hydrogen gas;
iv) heating said retort to a temperature between about 1000K and about 2000K for about 5 to about 50 hours;
v) cooling said retort to less than about 400K;
vi) exposing the gallium material within said retort to air to produce a powdered gallium phosphor material; and, vii) refiring said powdered gallium phosphor material under a gas comprising nitrogen, hydrogen, oxygen and hydrogen in the presence of an activator selected from the group consisting of europium, terbium, thulium, manganese, copper, silver, praseodymium, cerium, dysprosium, holmium, ytterbium, samarium, gadolinium, chlorine, bismuth, titanium, aluminum, sodium, lithium, potassium, indium, zinc, magnesium, silicon, germanium and combinations thereof and in the presence of a fluxing compound selected from the group consisting of sodium chloride, lithium chloride, potassium chloride, lithium fluoride, lithium silicate, chlorides of magnesium, strontium, and barium, magnesium fluoride, barium fluoride and combinations thereof.
